(19) United States
(12) Patent Application Publication
(10) Pub. No.: US 2026/0033055 A1
(43) Pub. Date: Jan. 29, 2026

(54) TRANSFER SUBSTRATE AND PREPARATION METHOD THEREOF, DISPLAY APPARATUS, AND TRANSFER METHOD FOR LIGHT-EMITTING ELEMENT

(71) Applicant: THE HONG KONG UNIVERSITY OF SCIENCE AND TECHNOLOGY (GUANGZHOU), Guangzhou (CN)

(72) Inventors: Yunda Wang, Guangzhou (CN); Qinhua Guo, Guangzhou (CN)

(21) Appl. No.: 19/342,690

(22) Filed: Sep. 29, 2025

Related U.S. Application Data
(63) Continuation-in-part of application No. PCT/CN2024/082145, filed on Mar. 18, 2024.

(30) Foreign Application Priority Data
Mar. 29, 2023 (CN) 202310326397.2

(51) Int. Cl. H10H 29/03; H10H 29/01; H10H 29/49

(52) U.S. Cl. CPC H10H 29/03; H10H 29/012; H10H 29/49

(57) ABSTRACT

A transfer substrate and a preparation method thereof, a display apparatus, and a transfer method for a light-emitting element are provided. The transfer substrate includes island structures spaced apart from each other, a conductive structure, and a connection portion. The island structures are configured to place to-be-transferred elements. The conductive structure is disposed on each island structure and configured to be electrically connected to the to-be-transferred elements. The connection portion is configured to connect at least two adjacent ones of the island structures. The connection portion is a separable connection structure, and is configured to separate, upon being actuated, the island structures connected by the connection portion. The conductive structure can meet the electrical connection needs of the light-emitting element, thereby reducing the dependence of the transferred light-emitting element on a wiring method in an array substrate.

### CROSS REFERENCE TO RELATED APPLICATIONS

The present application is a Continuation-In-Part Application of PCT Application No. PCT/CN2024/082145 filed on Mar. 18, 2024, which claims the benefit of Chinese Patent Application No. 202310326397.2 filed on Mar. 29, 2023. All the above are hereby incorporated by reference in their entirety.

### TECHNICAL FIELD

The present disclosure relates to the technical field of display devices, and in particular, to a transfer substrate and a preparation method thereof, a display apparatus, and a transfer method for a light-emitting element.

### BACKGROUND

Micro Light Emitting Diode (MicroLED) displays offer advantages such as high brightness, high resolution, good stability, long lifespan, and superior operating temperature performance. The MicroLED displays also inherit the benefits of Light Emitting Diodes (LEDs), including low power consumption, high color saturation, fast response speed, and strong contrast, making them highly promising for various applications.

However, during the preparation process, the transfer of MicroLEDs is often affected by multiple factors, resulting in poor applicability.

### SUMMARY

Embodiments of the present disclosure provide a transfer substrate and a preparation method thereof, a display apparatus, and a transfer method for a light-emitting element, which can improve transfer versatility.

According to a first aspect, embodiments of the present disclosure provide a transfer substrate, including: a plurality of island structures spaced apart from each other, a conductive structure, and a connection portion, where each of the island structures is configured to place a to-be-transferred element; the conductive structure disposed on each of the island structures, and configured to be electrically connected to the to-be-transferred element; and the connection portion is configured to connect at least two adjacent ones of the island structures; where the connection portion is a separable connection structure, and is configured to separate, upon being actuated, the island structures connected by the connection portion.

In some embodiments, the conductive structure includes a plurality of first signal lines and a plurality of second signal lines, any one of the first signal lines in combination with any one of the second signal lines is configured to be electrically connected to different terminals of the to-be-transferred element, and each of the first signal lines is disposed on the plurality of island structures and connected to the to-be-transferred elements on the plurality of island structures; where the first signal lines are disposed on the island structures, extend across a spaced-apart region between adjacent island structures, and are configured to be broken simultaneously within the spaced-apart region upon separation of two connected island structures.

In some embodiments, each of the second signal lines is disposed on the plurality of island structures and connected to the to-be-transferred elements on the plurality of island structures; where the second signal lines are disposed on the island structures, extend across a spaced-apart region between adjacent island structures, and are configured to be broken simultaneously within the spaced-apart region upon separation of two connected island structures.

In some embodiments, in a thickness direction of the island structure, projections of the first signal lines respectively overlap with projections of the connection portions.

In some embodiments, a plurality of the island structures are arranged side by side in an extension direction of each of the first signal lines.

In some embodiments, each of the island structures is further configured to provide a space for placing a plurality of to-be-transferred elements; a plurality of the first signal lines are disposed on the same island structure, including at least one of first signal lines connected in one-to-one correspondence to at least one of the to-be-transferred elements located on the same island structure and/or a first signal line simultaneously connected to at least one of the to-be-transferred elements located on the same island structure; and
a plurality of the second signal lines are disposed on the same island structure, including at least one of second signal lines connected in one-to-one correspondence to at least one of the to-be-transferred elements located on the same island structure and/or a second signal line simultaneously connected to at least one of the to-be-transferred elements located on the same island structure.

In some embodiments, the conductive structure further includes a first conductive portion disposed on each of the island structures and connected to the first signal line, and the first signal line is connected to the to-be-transferred element through the first conductive portion; and/or the conductive structure further includes a second conductive portion disposed on each of the island structures and connected to the second signal line, the second signal line is connected to the to-be-transferred element through the second conductive portion.

In some embodiments, the conductive structure further includes a driving circuit disposed on each of the island structures; the driving circuit is configured to be connected to the to-be-transferred element, and the first signal line and the second signal line are both connected to the driving circuit, for controlling turn-on or turn-off of the driving circuit, thereby controlling an operating state of the to-be-transferred element.

In some embodiments, a structural strength of at least a part of the connection portion is less than a structural strength of the island structure.

In some embodiments, the connection portion includes a main body portion and a weakened portion; a structural strength of the weakened portion is less than a structural strength of the main body portion and less than the structural strength of the island structure.

In some embodiments, a width of the weakened portion is less than a width of the main body portion; and/or a thickness of the weakened portion is less than a thickness of the main body portion.

In some embodiments, in a direction from the main body portion toward the weakened portion, a width of the connection portion decreases gradually; and/or in the direction from the main body portion toward the weakened portion, a thickness of the connection portion decreases gradually.

In some embodiments, the island structure and the connection portion form an integral structure, and a thickness of the connection portion is less than a thickness of the island structure.

In some embodiments, a material of the island structures includes silicon; and/or a thickness of each of the island structures is W, where W satisfies 20 μm≤W≤500 μm.

In some embodiments, the connection portion includes a base and a metal wiring layer stacked on one side of the base; and/or the connection portion includes highly doped polycrystalline silicon;
the plurality of first signal lines are respectively disposed on the connection portions, and/or
the plurality of second signal lines are respectively disposed on the connection portions.

According to a second aspect, embodiments of the present disclosure provide a display apparatus, including: a plurality of island structures separated from the transfer substrate in any of the aforementioned embodiments; and a plurality of light-emitting elements, where the plurality of light-emitting elements are disposed on the plurality of island structures respectively, each of the light-emitting elements is electrically connected to the conductive structure on the island structure where the light-emitting element is located.

According to a third aspect, embodiments of the present disclosure provide a transfer method for a light-emitting element, the transfer method being applied to the transfer substrate in any of the aforementioned embodiments, including:
disposing a plurality of light-emitting elements on a plurality of island structures of the transfer substrate, and electrically connecting each of the light-emitting elements to the conductive structure on the island structure where the light-emitting element is located;
actuating a connection portion of a target island structure based on preset target information, such that the target island structure, along with the light-emitting element and at least a part of the conductive structure that are located on the target island structure, is separated from an adjacent island structure connected to the target island structure, to form a display module; and
transferring the display module to a target substrate and connecting the display module to the target substrate to obtain a display apparatus.

According to a fourth aspect, embodiments of the present disclosure provide a preparation method of a transfer substrate, including:
providing an initial substrate, the initial substrate having a plurality of first regions spaced apart from each other, and second regions respectively located between adjacent first regions;
disposing a shielding assembly on one side of the initial substrate in a thickness direction, the shielding assembly including a first shielding portion disposed in each of the first regions; and
performing etching from a side of the shielding assembly away from the initial substrate, such that a thickness at each of the second regions is less than a thickness at each of the first regions, and obtaining the transfer substrate after the etching is completed.

Embodiments of the present disclosure provide a transfer substrate and a preparation method thereof, a display apparatus, and a transfer method for a light-emitting element. When a single island structure is separated from adjacent island structures connected thereto, a light-emitting element located on the single island structure and part of a conductive structure are also transferred together. On this basis, since part of the conductive structure remains electrically connected to the light-emitting element, this part of the conductive structure can still meet electrical connection requirements of the light-emitting element, thereby reducing the dependence of the transferred light-emitting element on a wiring method in an array substrate. Moreover, the presence of the island structure can reduce the dependence of the light-emitting element on a film layer structure in the array substrate. Thus, the light-emitting element can be transferred to different types of target substrates, and even when the target substrate has flexible or partially flexible characteristics, it can be used to manufacture curved display or flexible display modules, offering strong versatility.

### BRIEF DESCRIPTION OF THE DRAWINGS

To describe the technical solutions in the embodiments of this application, the following briefly describes the accompanying drawings required for the embodiments. A person of ordinary skill in the art may still derive other accompanying drawings from these accompanying drawings without creative efforts.

FIG. 1 is a schematic structural diagram of a transfer substrate according to an embodiment of the present disclosure;

FIG. 2 is a cross-sectional schematic view taken along line A-A shown in FIG. 1;

FIG. 3 is a schematic structural diagram of another transfer substrate according to an embodiment of the present disclosure;

FIG. 4 is a schematic structural diagram of yet another transfer substrate according to an embodiment of the present disclosure;

FIG. 5 is a schematic structural diagram of an island structure in yet another transfer substrate according to an embodiment of the present disclosure;

FIG. 6 is a schematic structural diagram of an island structure in yet another transfer substrate according to an embodiment of the present disclosure;

FIG. 7 is a schematic structural diagram between adjacent island structures in yet another transfer substrate according to an embodiment of the present disclosure;

FIG. 8 is a schematic structural diagram between adjacent island structures in yet another transfer substrate according to an embodiment of the present disclosure;

FIG. 9 is a cross-sectional structural view taken along line B-B shown in FIG. 7;

FIG. 10 is a schematic structural diagram of a display apparatus according to an embodiment of the present disclosure;

FIG. 11 is a flowchart of a transfer method for a light-emitting element according to an embodiment of the present disclosure;

FIG. 12 is a flowchart of a preparation method of a transfer substrate according to an embodiment of the present disclosure; and

FIG. 13a to FIG. 13c are schematic structural diagrams of a process of a preparation method of a transfer substrate according to an embodiment of the present disclosure.

### REFERENCE NUMERALS

10: Island structure;
20: Connection portion;
21: Main body portion;
22: Weakened portion;
30: Conductive structure;
40: To-be-transferred element;
41: Light-emitting element;
50: Initial substrate;
60: Shielding assembly;
61: First shielding portion;
L1: First signal line;
L2: Second signal line;
D1: First conductive portion;
D2: Second conductive portion;
Q: Driving circuit;
A1: First region;
A2: Second region;
X: First direction;
Y: Second direction;
Z: Thickness direction.

### DETAILED DESCRIPTION

Features of various aspects and exemplary embodiments of this application are described below in detail. To make the objectives, technical solutions, and advantages of this application clearer, this application is further described in detail below with reference to the accompanying drawings and embodiments. It should be understood that the embodiments described herein are merely used to explain this application, rather than to limit this application. A person skilled in the art can implement this application without some of these specific details. The following description of the embodiments is intended only to provide a better understanding of this application by illustrating examples of this application.

It should be noted that relational terms herein such as first and second are merely used to distinguish one entity or operation from another entity or operation without necessarily requiring or implying any actual such relationship or order between such entities or operations. In addition, terms “include”, “comprise”, or their any other variations are intended to cover a non-exclusive inclusion, such that a process, a method, an article, or a device that includes a series of elements not only includes those elements, but also includes other elements that are not explicitly listed, or also includes inherent elements of the process, the method, the article, or the device. Without more restrictions, the elements defined by the sentence “including . . . ” do not exclude the existence of other identical elements in a process, method, article, or device including the elements.

In a manufacturing process of MicroLED displays, it is usually necessary to first grow a plurality of MicroLEDs on an original substrate (such as a sapphire substrate) through molecular epitaxy. The MicroLEDs can form a MicroLED array. Then, the MicroLEDs are stripped from the original substrate using laser lift-off technology, and a transfer head is used to transfer the MicroLEDs to predetermined positions on an array substrate, where the MicroLEDs are bonded to the array substrate to form a MicroLED display.

However, during this process, the transfer of MicroLEDs is limited by the structure and wiring layout of the array substrate, resulting in MicroLEDs only being transferable to specific array substrates, which imposes significant limitations.

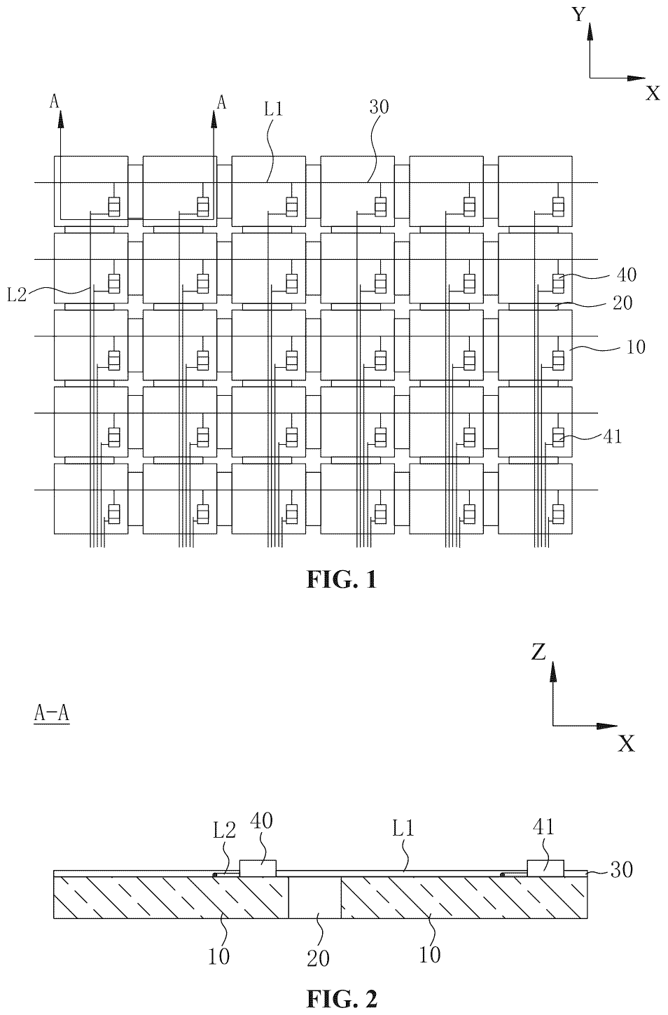

To address the above issues, in a first aspect, referring to FIG. 1 and FIG. 2, an embodiment of the present disclosure provides a transfer substrate, including a plurality of island structures 10 spaced apart from each other, a conductive structure 30, and a connection portion 20. The island structure 10 is configured to place a to-be-transferred element 40. The conductive structure 30 is disposed on each island structure 10 and is configured to be electrically connected to the to-be-transferred element 40. The connection portion 20 is configured to connect at least two adjacent ones of the island structures 10. The connection portion 20 is a separable connection structure, and is configured to separate, upon being actuated, the island structures 10 connected by the connection portion 20.

The transfer substrate is configured to separate different island structures 10 by actuating the connection portion 20.

The transfer substrate is configured to achieve the transfer of the to-be-transferred element 40. The to-be-transferred element 40 includes but is not limited to a light-emitting element 41. For convenience of description, the subsequent embodiments of the present disclosure are described with the to-be-transferred element 40 being the light-emitting element 41. The light-emitting element 41 includes but is not limited to a MicroLED.

A plurality of light-emitting elements 41 may be disposed on the plurality of island structures 10 uniformly or according to a preset rule. The light-emitting element 41 may be located on one side of the island structure 10 in a thickness direction Z of the island structure 10. Each island structure 10 may have only one light-emitting element 41 disposed thereon, or may have a plurality of light-emitting elements 41 disposed thereon, which is not limited in this embodiment of the present disclosure.

Some of the island structures 10 may be arranged side by side in a single direction or in different directions. For example, the island structures 10 are arranged in an array along a first direction X and a second direction Y, with the first direction X intersecting the second direction Y. The size and shape of the island structure 10 are not limited in this embodiment of the present disclosure. For example, a projection of the island structure 10 in the thickness direction Z may be square, circular, or in other polygonal shapes.

Furthermore, a specific positional relationship of the light-emitting element 41 relative to the island structure 10 is also not limited in this embodiment of the present disclosure. A projection of the light-emitting element 41 in the thickness direction Z may be located at the center of the projection of the island structure 10 in the thickness direction Z, or may be located at the edge of the projection of the island structure 10 in the thickness direction Z.

The conductive structure 30 is disposed on each island structure 10. The conductive structure 30 may be located on a surface of the island structure 10 in the thickness direction Z, or the conductive structure 30 may be located inside the island structure 10, or the conductive structure 30 may be partially located on the surface of the island structure 10 in the thickness direction Z and partially located inside the island structure 10. Moreover, the parts of the conductive structure 30 disposed on different island structures 10 may be electrically connected to each other or may be insulated from each other, which is not limited in this embodiment of the present disclosure.

The conductive structure 30 can control the light-emitting element 41 to achieve a light-emitting function. The conductive structure 30 may have a wiring structure inside, and control of the light-emitting element 41 is achieved through wiring. The specific structural layout of the conductive structure 30 is not limited in this embodiment of the present disclosure.

Each connection portion 20 is configured to connect adjacent island structures 10. The specific structural form of the connection portion 20 is not limited in this embodiment of the present disclosure. Optionally, the connection portion 20 and the island structure 10 may form an integral structure. The connection portion 20 and the island structure 10 can be prepared and formed simultaneously. The strength of the connection portion 20 is lower than the strength of the island structure 10.

It should be noted that the conductive structure 30 may be disposed on the connection portion 20, that is, a projection of the conductive structure 30 in the thickness direction Z overlaps with a projection of the connection portion 20 in the thickness direction Z; or the conductive structure 30 may not be disposed on the connection portion 20, meaning that the projection of the conductive structure 30 in the thickness direction Z does not overlap with the projection of the connection portion 20 in the thickness direction Z.

In this embodiment of the present disclosure, since each connection portion is a separable connection structure, the connection portion 20 can, after being actuated, separate the island structures 10 connected by the connection portion, thereby enabling the separation of a specific island structure 10 from the adjacent island structure 10 connected thereto. Specifically, the actuation mentioned here refers to that the connection portion 20 moves or is activated to a certain state, thereby causing the island structures 10 connected by the connection portion to separate from each other. The movement generated by the connection portion 20 may include, but is not limited to, at least a part of the connection portion 20 breaking, fracturing, tearing, or opening. Further, the movement may be that a connection position between the connection portion 20 and the island structure 10 breaks, fractures, tears, or opens.

After a single island structure 10 is separated from an adjacent island structure 10, the light-emitting element 41 located thereon and a part of the conductive structure 30 are also transferred together. On this basis, since a part of the conductive structure 30 remains electrically connected to the light-emitting element 41, this part of the conductive structure 30 can still meet the electrical connection needs of the light-emitting element 41, thereby reducing the dependence of the transferred light-emitting element 41 on the wiring method in the array substrate. Moreover, the existence of the island structure 10 can reduce the dependence of the light-emitting element 41 on the film layer structure in the array substrate. Thus, the light-emitting element 41 can be transferred to different types of target substrates, and when the target substrate is flexible or partially flexible, it can be used to manufacture curved displays or flexible display modules, offering strong versatility.

In some embodiments, as shown in FIG. 1 and FIG. 2, the conductive structure 30 includes a plurality of first signal lines L1 and a plurality of second signal lines L2. Any one of the first signal lines L1 in combination with any one of the second signal lines L2 is configured to be electrically connected to different terminals of the to-be-transferred element 40. The first signal line L1 is disposed on the plurality of island structures 10 and connected to the to-be-transferred elements in the plurality of island structures. The first signal lines are disposed on the island structures, extend across a spaced-apart region between adjacent island structures, and are configured to be broken simultaneously within the spaced-apart region upon separation of two connected island structures. When two connected island structures are separated, the first signal lines on the two island structures are simultaneously separated.

The transfer substrate is configured to separate different parts of the first signal line L1 corresponding to different island structures 10 by actuating the connection portions 20.

Any one of the first signal lines L1 and any one of the second signal lines L2 are electrically connected to both ends of the light-emitting element 41. The first signal line L1 is configured to transmit a first-type signal to the light-emitting element 41, and the second signal line L2 is configured to transmit a second-type signal to the light-emitting element 41. The first-type signal and the second-type signal are of different types. For example, one of the first-type signal and the second-type signal is a data signal, and the other is a scan signal line; the two signals work together to control whether the light-emitting element 41 operates.

The first signal line L1 is electrically connected to a plurality of light-emitting elements 41. Compared to a solution where each first signal line L1 is only electrically connected to one single light-emitting element 41, this design can reduce the number of the first signal lines L1 and decrease the wiring density in the transfer substrate.

When the connection portion 20 is actuated, the adjacent island structures 10 connected by the connection portion 20 separate from each other, and simultaneously, different parts of the first signal line L1 corresponding to the different island structures 10 also separate from each other. In other words, when a single island structure 10 separates from other island structures 10, the part of the first signal line L1 located on that island structure 10 is transferred together with the light-emitting element 41, thereby meeting the electrical connection needs of the light-emitting element 41, reducing the dependence of the light-emitting element 41 on the wiring layout in the array substrate, and improving transfer versatility.

A specific positional relationship of the first signal line L1 relative to the island structure 10 is not limited in this embodiment of the present disclosure. For example, at least some island structures 10 are arranged side by side along the first direction X, and the first signal line L1 also extends along the first direction X and is disposed on the island structures 10 arranged side by side in the first direction X.

As for the second signal lines L2, each second signal line L2 may be electrically connected to only a single light-emitting element 41, or may be electrically connected to a plurality of light-emitting elements 41, which is not limited in this embodiment of the present disclosure.

It should be noted that the transfer substrate provided in this embodiment of the present disclosure can not only meet the transfer needs of the light-emitting elements 41 but also achieve batch detection functionality for the light-emitting elements 41. Specifically, before the transfer of the light-emitting element 41, a plurality of light-emitting elements 41 are disposed on a plurality of island structures 10. At this time, the same first signal line L1 can be electrically connected to a plurality of light-emitting elements 41 located on different island structures 10, enabling the same first signal line L1 to simultaneously transmit the first-type signal to multiple light-emitting elements 41, thereby achieving simultaneous detection of multiple light-emitting elements 41, achieving batch detection effects, and improving detection efficiency.

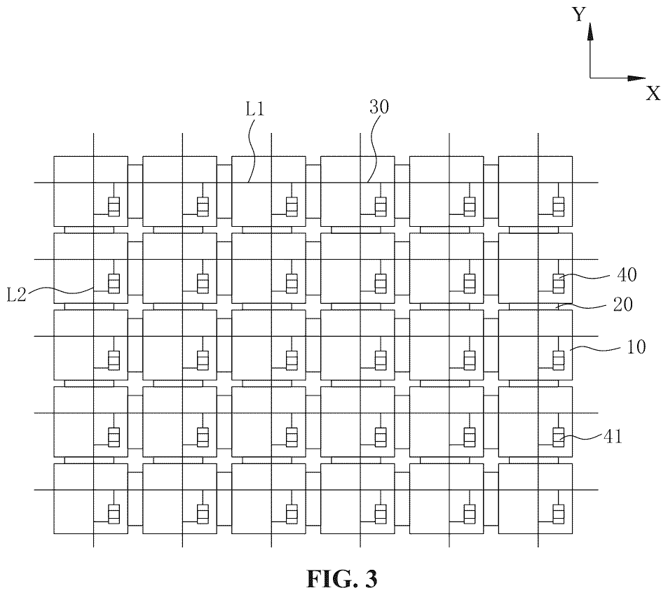

In some embodiments, referring to FIG. 3, a single extended second signal line L2 is disposed on the plurality of island structures 10 and connected to the to-be-transferred elements in the plurality of island structures. The second signal line is disposed on each island structure, extends across a spaced-apart region between adjacent island structures, and is configured to be broken simultaneously within the spaced-apart region upon separation of two connected island structures. When the island structure where it is located is separated from the connected island structure, the second signal line is simultaneously separated from the second signal line on the connected island structure.

The transfer substrate is configured to separate different parts of the second signal line L2 corresponding to different island structures 10 by actuating some of the connection portions 20.

The relative relationship between the first signal line L1 and the second signal line L2 is not limited in this embodiment of the present disclosure. For example, the first signal line L1 extends along the first direction X, and the second signal line L2 extends along the second direction Y. The first direction X and the second direction Y intersect, that is, extension directions of the first signal line L1 and the second signal line L2 are not parallel. This design allows multiple first signal lines L1 and multiple second signal lines L2 to form a detection region for accommodating the light-emitting elements 41 through selection, thereby enabling the detection of the yield rate of the light-emitting elements 41.

The specific positional relationship of the second signal line L2 relative to the island structure 10 is not limited in this embodiment of the present disclosure. For example, at least some island structures 10 are arranged side by side along the second direction Y, and the second signal line L2 also extends along the second direction Y and is disposed on the island structures 10 arranged side by side in the second direction Y.

The second signal line L2 is electrically connected to a plurality of light-emitting elements 41. Compared to a solution where each second signal line L2 is only electrically connected to a single light-emitting element 41, this design can reduce the number of the second signal lines L2 and decrease the wiring density in the transfer substrate.

When the connection portion 20 is actuated, the adjacent island structures 10 connected by the connection portion 20 separate from each other, and simultaneously, different parts of the second signal line L2 corresponding to different island structures 10 also separate from each other. In other words, when a single island structure 10 separates from other island structures 10, the part of the second signal line L2 located on that island structure 10 is transferred together with the light-emitting element 41, thereby meeting the electrical connection needs of the light-emitting element 41, reducing the dependence of the light-emitting element 41 on the wiring layout in the array substrate, and improving transfer versatility.

In this embodiment of the present disclosure, since each single first signal line L1 can connect multiple light-emitting elements 41 and each single second signal line L2 can connect multiple light-emitting elements 41, different detection modes can be applied to the light-emitting elements 41 by controlling different first signal lines L1 and second signal lines L2 to transmit specific signals, respectively. Specifically, when a single first signal line L1 and a single second signal line L2 are controlled to transmit specific signals, respectively, light emission detection of a specific light-emitting element 41 can be achieved, i.e., a single-point detection mode. When all the first signal lines L1 and all the second signal lines L2 are controlled to transmit specific signals, respectively, light emission detection of all the light-emitting elements 41 can be achieved, i.e., an overall detection mode. When some of the first signal lines L1 and some of the second signal lines L2 are controlled to transmit specific signals, respectively, light emission detection of partial light-emitting elements 41 can be achieved, i.e., a partial detection mode. When a single first signal line L1 and all the second signal lines L2 transmit specific signals, respectively, light emission detection of a single row of light-emitting elements 41 can be achieved; when a single second signal line L2 and all the first signal lines L1 transmit specific signals, respectively, light emission detection of a single column of light-emitting elements 41 can be achieved, i.e., a row/column detection mode.

It should be noted that the types of specific signals transmitted by the first signal line L1 and the second signal line L2 are not limited in this embodiment of the present disclosure. For example, only when the first signal line L1 transmits a high-level signal and the second signal line L2 transmits a low-level signal can the light-emitting element 41 electrically connected to the first signal line L1 and the second signal line L2 operate normally. That is, when no signal or a low-level signal is transmitted in the first signal line L1, the light-emitting element 41 electrically connected thereto cannot be driven to work; when no signal or a high-level signal is transmitted in the second signal line L2, the light-emitting element 41 electrically connected thereto cannot be driven to work.

In some embodiments, a projection of the first signal line L1 in the thickness direction Z of the island structure 10 overlaps with the projection of the connection portion 20 in the thickness direction Z, meaning that a part of the structure of the first signal line L1 is located on the connection portion 20. The part of the structure of the first signal line L1 located on the connection portion 20 may be on the surface of the connection portion 20 in the thickness direction Z, or may be inside the connection portion 20, which is not limited in this embodiment of the present disclosure.

As can be known from the foregoing content, a single first signal line L1 is simultaneously disposed on a plurality of island structures 10. When the connection portion 20 is actuated, the adjacent island structures 10 connected by the connection portion 20 separate from each other, and at the same time, different parts of the single first signal line L1 corresponding to the different island structures 10 need to be disconnected.

On this basis, in this embodiment of the present disclosure, a part of the structure of the first signal line L1 is disposed on the connection portion 20. This design ensures that when the connection portion 20 is actuated, the part of the structure of the first signal line L1 located on the connection portion 20 can fracture along with the actuation of the connection portion 20, thereby achieving the effect of simultaneous transfer of the island structure 10, the light-emitting element 41 located on the island structure 10, and a part of the structure of the first signal line L1, meeting the transfer needs.

Similarly, in other embodiments, the projection of the second signal line L2 in the thickness direction Z of the island structure 10 overlaps with the projection of the connection portion 20 in the thickness direction Z, meaning that a part of the structure of the second signal line L2 is located on the connection portion 20. The part of the structure of the second signal line L2 located on the connection portion 20 may be on the surface of the connection portion 20 in the thickness direction Z, or may be inside the connection portion 20, which is not limited in this embodiment of the present disclosure.

It should be noted that when a driving circuit electrically connected to at least one of the first signal line L1, the second signal line L2, and the light-emitting element 41 is disposed on the island structure 10, the driving circuit can be transferred together with the island structure 10, the light-emitting element 41 located on the island structure 10, a part of the structure of the first signal line L1, and a part of the structure of the second signal line.

In some embodiments, a plurality of the island structures 10 are arranged side by side in the extension direction of the first signal line L1.

A single first signal line L1 is disposed on multiple island structures 10. On this basis, by setting the side-by-side direction of at least some of the island structures 10 to be the extension direction of the first signal line L1, it is more conducive to the layout and extension of the first signal line L1 on the multiple island structures 10, thereby reducing the wiring difficulty of the first signal line L1 and improving the reliability of the relative position between the island structure 10 and the first signal line L1.

Similarly, in other embodiments, at least some of the island structures 10 are arranged side by side in the extension direction of the second signal line L2. Optionally, a plurality of island structures 10 are arranged side by side along the first direction X and the second direction Y, respectively. The first signal line L1 extends along the first direction X and is disposed on the island structures 10 arranged side by side in the first direction X. The second signal line L2 extends along the second direction Y and is disposed on the island structures 10 arranged side by side in the second direction Y.

In some embodiments, each of the island structures is further configured to provide a space for placing a plurality of to-be-transferred elements; a plurality of first signal lines are disposed on the same island structure, including at least one of first signal lines connected in one-to-one correspondence to at least one of the to-be-transferred elements located on the same island structure and/or a first signal line simultaneously connected to at least one of the to-be-transferred elements located on the same island structure; a plurality of second signal lines are disposed on the same island structure, including at least one of second signal lines connected in one-to-one correspondence to at least one of the to-be-transferred elements located on the same island structure and/or a second signal line simultaneously connected to at least one of the to-be-transferred elements located on the same island structure.

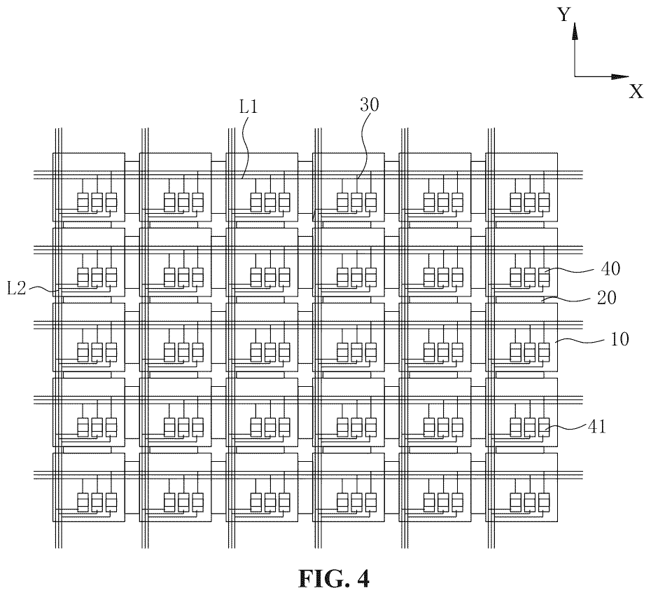

In one embodiment, referring to FIG. 4, the plurality of first signal lines L1 disposed on the same island structure 10 only include a plurality of first signal lines L1 connected in one-to-one correspondence to a plurality of to-be-transferred elements 40 located on the same island structure 10. Optionally, the plurality of first signal lines L1 disposed on the same island structure may alternatively include at least one of first signal lines connected in one-to-one correspondence to at least one of the to-be-transferred elements located on the same island structure and/or a first signal line simultaneously connected to at least one of the to-be-transferred elements located on the same island structure.

Referring to FIG. 4, the plurality of second signal lines L2 disposed on the same island structure 10 only include a plurality of second signal lines L2 connected in one-to-one correspondence to a plurality of to-be-transferred elements 40 located on the same island structure 10. Optionally, the plurality of second signal lines L2 disposed on the same island structure may alternatively include at least one of second signal lines connected in one-to-one correspondence to at least one of the to-be-transferred elements located on the same island structure and/or a second signal line simultaneously connected to at least one of the to-be-transferred elements located on the same island structure.

The island structure 10 may also be provided with a plurality of light-emitting elements 41, thereby reducing the number of island structures 10, which can reduce, to some extent, the size of the transfer substrate, or allow more light-emitting elements 41 to be arranged on a transfer substrate of a specific size to improve transfer efficiency. The number and color of light-emitting elements 41 on a single island structure 10 are not limited in this embodiment of the present disclosure. For example, three light-emitting elements 41 of different colors may be disposed on a single island structure 10, and the three light-emitting elements 41 of different colors may be used to form one pixel repeating unit.

The arrangement of different light-emitting elements 41 on a single island structure 10 is not limited in this embodiment of the present disclosure. Different light-emitting elements 41 on a single island structure 10 may be arranged side by side in the same direction or arranged in different directions. The connection method of different light-emitting elements 41 on a single island structure 10 is not limited in this embodiment of the present disclosure.

In this embodiment of the present disclosure, a plurality of light-emitting elements 41 are disposed on each island structure 10. Multiple first signal lines L1 can simultaneously pass through the same island structure 10, thereby enabling electrical connection with different light-emitting elements 41. Multiple second signal lines L2 can simultaneously pass through the same island structure 10, thereby enabling electrical connection with different light-emitting elements 41, meeting the wiring needs of each light-emitting element 41 while reducing the number of island structures 10. Moreover, when the light-emitting elements 41 need to be transferred, multiple light-emitting elements 41 can be transferred simultaneously as one pixel repeating unit with the same island structure 10 to the corresponding array substrate, thereby reducing the number of transfers, improving the transfer effect, and enhancing the reliability of the relative positions among the multiple light-emitting elements 41 within the pixel repeating unit.

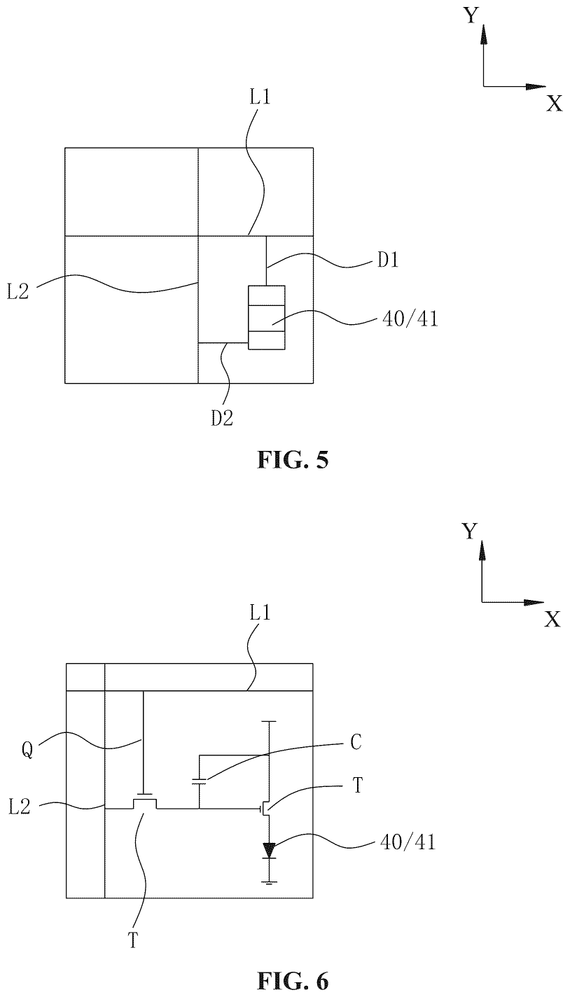

In some embodiments, referring to FIG. 5, the conductive structure further includes a first conductive portion D1 disposed on the island structure 10 and connected to the first signal line L1. The first signal line is connected to the to-be-transferred element 40 through the first conductive portion D1.

The first conductive portion D1 is configured to achieve the connection between the light-emitting element 41 and the first signal line L1. The first conductive portion D1 can be in direct contact with the light-emitting element 41 and the first signal line L1, respectively, to achieve the signal transmission function, thereby realizing passive driving of the light-emitting element 41.

The first signal line L1 may be located on the surface of the island structure 10 in the thickness direction or inside the island structure 10. When the first signal line L1 is located on the surface of the island structure 10 in the thickness direction, the first conductive portion D1 may also be located on the surface of the island structure 10 in the thickness direction; when the first signal line L1 is located inside the island structure 10, the first conductive portion D1 may be disposed in a via of the island structure 10, achieving electrical connection between the first signal line L1 and the first conductive portion D1 through the via.

Similarly, in other embodiments, the transfer substrate further includes a second conductive portion D2 disposed on the island structure 10 and connected to the second signal line L2. The second signal line is connected to the to-be-transferred element 40 through the second conductive portion D2. The second conductive portion D2 is configured to achieve the connection between the light-emitting element 41 and the second signal line L2. The second conductive portion D2 can be in direct contact with the light-emitting element 41 and the second signal line L2, respectively, to achieve the signal transmission function, thereby realizing passive driving of the light-emitting element 41.

It should be noted that when a specific light-emitting element 41 needs to be transferred, the first conductive portion D1 and the second conductive portion D2 electrically connected thereto will be transferred together with the light-emitting element 41.

In some embodiments, referring to FIG. 6, the conductive structure further includes driving circuits Q disposed on each of the island structures 10. The driving circuit Q is configured to be connected to the to-be-transferred element 40. Both the first signal line L1 and the second signal line L2 are connected to the driving circuit, for controlling turn-on or turn-off of the driving circuit Q, thereby controlling an operating state of the to-be-transferred element, to achieve control over whether the to-be-transferred element 40 works.

The driving circuit Q and the light-emitting element 41 are both disposed on the island structure 10. The structural form of the driving circuit Q is not limited in this embodiment of the present disclosure. For example, the driving circuit Q may include a driving transistor T and a capacitor C. The driving circuit Q may be in a circuit form such as 2T1C (2 Transistor 1 Capacitor), 7T1C (7 Transistor 1 Capacitor), or 8T1C (8 Transistor 1 Capacitor), or the driving circuit Q may include a Complementary Metal Oxide Semiconductor (CMOS).

Both the first signal line L1 and the second signal line L2 are connected to the driving circuit Q, and the driving circuit Q is connected to the light-emitting element 41, thereby enabling active driving of the light-emitting element 41. The driving circuit Q can be formed with the aid of multiple stacked film layer structures in the island structure 10. For example, the island structure 10 may include an active layer, a gate layer, and a source-drain layer. The gate layer is provided with a gate, the active layer is provided with an active structure, and the source-drain layer is provided with a source and a drain. The source is connected to a source region in the active structure, and the drain is connected to a drain region in the active structure, thereby forming the driving transistor in the driving circuit Q.

It should be noted that when a specific light-emitting element 41 needs to be transferred, the driving circuit Q will be transferred together with the light-emitting element 41 to the target substrate to form a display apparatus.

In some embodiments, a structural strength of at least a part of the connection portion 20 is less than a structural strength of the island structure 10.

The “structural strength” mentioned in this embodiment of the present disclosure refers to: the property of the corresponding structure to resist fracture. A higher structural strength indicates a lower possibility of the structure fracturing under external force; a lower structural strength indicates a higher possibility of the structure fracturing under external force. Therefore, compared to the island structure 10, at least a part of the connection portion 20 is more prone to fracture and damage under external force.

During the transfer process, the connection portion 20 needs to be actuated to achieve separation between adjacent island structures 10 connected by the connection portion. At this time, the connection portion 20 may experience damage or fracture, while the island structure 10 needs to remain structurally intact and reliable. On this basis, in this embodiment of the present disclosure, the structural strength of at least a part of the connection portion 20 is set to be less than the structural strength of the island structure 10, so that when the connection portion 20 is actuated due to factors such as external force, the risk of damage and deformation of the island structure 10 can be reduced, improving transfer reliability.

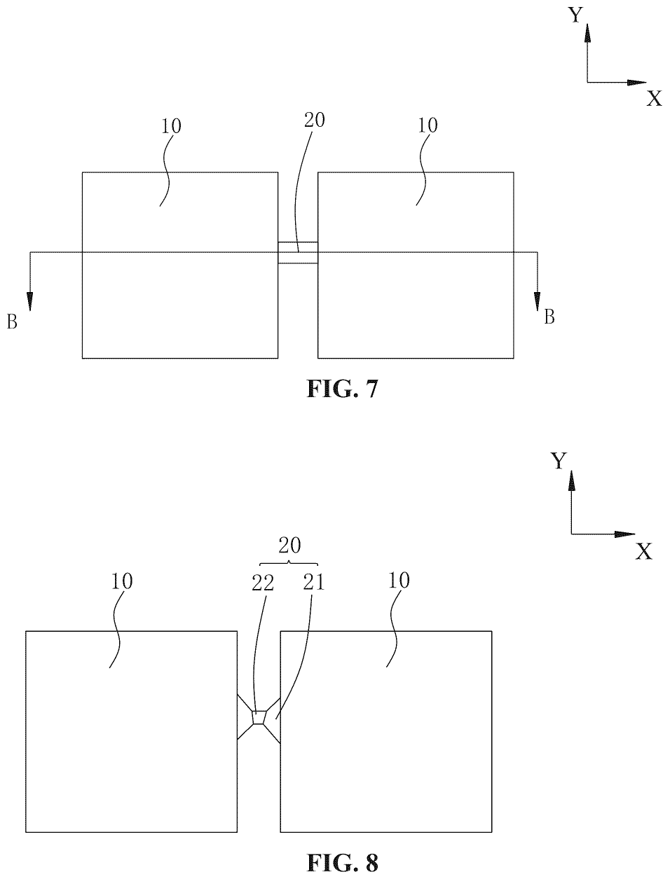

For example, as shown in FIG. 7, the connection portion 20 for connecting two adjacent island structures 10 in the first direction X has a size in the second direction Y that is smaller than a size of the island structure 10 in the second direction, so that the structural strength of the connection portion 20 is less than the structural strength of the island structure 10.

In some embodiments, referring to FIG. 8, the connection portion 20 includes a main body portion 21 and a weakened portion 22. A structural strength of the weakened portion 22 is less than a structural strength of the main body portion 21 and less than the structural strength of the island structure.

Parameters such as the material, shape, and size of the weakened portion 22 are not limited in this embodiment of the present disclosure, as long as the structural strength of the weakened portion 22 is less than the structural strength of the main body portion 21. For example, the weakened portion 22 and the main body portion 21 may be made of the same material and formed integrally, and then the structural strength at a part of the connection portion 20 is reduced through processing, thereby forming the weakened portion 22. Alternatively, the material of the weakened portion 22 may be different from the material of the main body portion 21. The weakened portion 22 and the main body portion 21 are prepared separately and then connected and fixed to each other. The connection method includes but is not limited to bonding and welding, etc.

In this embodiment of the present disclosure, by providing the weakened portion 22 on the connection portion 20, when the light-emitting element 41 needs to be transferred, it can be ensured that the connection portion 20 can be quickly actuated at the weakened portion 22, achieving separation between adjacent island structures 10 connected by the connection portion, thereby meeting the transfer needs.

In some embodiments, a width of the weakened portion 22 is less than a width of the main body portion 21.

Depending on the position of the connection portion 20, a width direction of the weakened portion 22 also differs. For example, a plurality of island structures 10 are arranged side by side along the first direction X and the second direction Y, respectively. For the connection portion 20 located between two adjacent island structures 10 in the first direction X, the width direction of both the weakened portion 22 and the main body portion 21 is the second direction Y; for the connection portion 20 located between two adjacent island structures 10 in the second direction Y, the width direction of both the weakened portion 22 and the main body portion 21 is the first direction X.

In this embodiment of the present disclosure, by controlling the width of the weakened portion 22 to be less than the width of the main body portion 21, the structural strength of the weakened portion 22 can be made less than the structural strength of the main body portion 21, thereby ensuring that the connection portion 20 can be quickly actuated at the weakened portion 22 to achieve separation between adjacent island structures 10, thus meeting the transfer needs.

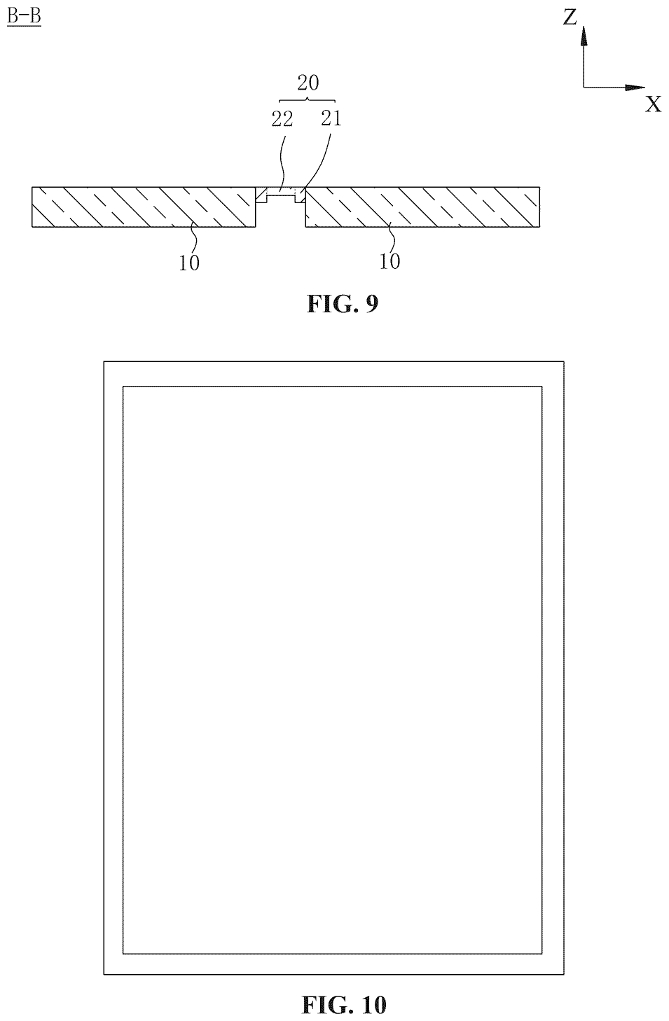

In other embodiments, referring to FIG. 9, a thickness of the weakened portion 22 is less than a thickness of the main body portion 21, that is, the dimension of the weakened portion 22 in the thickness direction Z is less than the dimension of the main body portion 21 in the thickness direction Z.

Similar to the above embodiment, by controlling the thickness of the weakened portion 22 to be less than the thickness of the main body portion 21, the structural strength of the weakened portion 22 can also be made less than the structural strength of the main body portion 21, thereby ensuring that the connection portion 20 can be quickly actuated at the weakened portion 22 to achieve separation between adjacent island structures 10, thus meeting the transfer needs.

In some embodiments, as shown in FIG. 8, in a direction from the main body portion 21 toward the weakened portion 22, the width of the connection portion 20 decreases gradually. In other words, in the connection portion 20, a part closer to the weakened portion 22 has a smaller width, while a part farther away from the weakened portion 22 has a larger width. For example, the projection of the connection portion 20 in the thickness direction Z is a butterfly-like structure, and a part with the smallest width is the weakened portion 22.

This design can further increase the probability of actuation occurring at the weakened portion 22, thereby achieving precise control over the actuation position in the connection portion 20, reducing the impact of the actuation of the connection portion 20 on the island structure 10, and improving transfer accuracy and reliability.

Similarly, in other embodiments, in the direction from the main body portion 21 toward the weakened portion 22, the thickness of the connection portion 20 decreases gradually.

In some embodiments, the island structure 10 and the connection portion 20 form an integral structure, and the thickness of the connection portion 20 is less than the thickness of the island structure 10.

The island structure 10 and the connection portion 20 are made of the same material and can be prepared and formed simultaneously. On this basis, in this embodiment of the present disclosure, the thickness of the connection portion 20 is set to be less than the thickness of the island structure 10, thereby increasing the probability of actuation of the connection portion 20 during the transfer process and reducing the risk of damage and deformation of the island structure 10, improving transfer reliability.

It should be noted that the thickness of the island structure 10 mentioned in this embodiment of the present disclosure refers to an average thickness of the island structure 10, and the thickness of the connection portion 20 refers to an average thickness of the connection portion 20. The thickness at some parts in the connection portion 20 may also be greater than the thickness at some parts in the island structure 10.

In other embodiments, the island structure 10 and the connection portion 20 form an integral structure, and the width of the connection portion 20 is less than the width of the island structure 10.

In some embodiments, the material of the island structure 10 includes silicon. The silicon in the island structure 10 ensures the density and stability of the island structure 10, thereby providing support and protection for the light-emitting element 41 to a certain extent.

In some embodiments, the thickness of the island structure 10 is W, where W satisfies 20 μm≤W≤500 μm. As known from the foregoing content, the island structure 10 will be transferred together with the light-emitting element 41 to the target substrate to form a display apparatus. On this basis, if the thickness of the island structure 10 is excessively small, its support and protection for the light-emitting element 41 are insufficient, making it prone to damage risks due to factors such as external force; if the thickness of the island structure 10 is excessively large, it may easily lead to an excessive thickness of the final display apparatus, which is not conducive to a thin and light design. Therefore, in this embodiment of the present disclosure, the thickness of the island structure 10 is set to satisfy 20 μm≤W≤500 μm.

In some embodiments, the connection portion 20 includes a base and a metal wiring layer stacked on one side of the base.

In this embodiment of the present disclosure, the connection portion 20 is not a single film layer structure, but includes at least two different film layers stacked together. The base includes but is not limited to materials such as polyimide, and the metal wiring layer includes but is not limited to metal materials such as gold, aluminum, and copper.

In some embodiments, the connection portion 20 includes highly doped polycrystalline silicon.

The plurality of first signal lines are respectively disposed on the connection portions, and/or
the plurality of second signal lines are respectively disposed on the connection portions.

According to a second aspect, referring to FIG. 10, an embodiment of the present disclosure provides a display apparatus, including a plurality of light-emitting elements and a plurality of island structures separated from the transfer substrate according to any implementation of the first aspect. The plurality of light-emitting elements are disposed on the plurality of island structures respectively, and each light-emitting element is electrically connected to the conductive structure on the island structure where the light-emitting element is located.

In the early stage of the preparation process, the light-emitting elements can be disposed on the island structures and electrically connected to the conductive structure. During the preparation process, any island structure, along with the light-emitting element located thereon and at least a part of the conductive structure, can be transferred together from any transfer substrate to another substrate and connected, thereby forming a display apparatus.

The presence of the conductive structure can reduce the dependence of the light-emitting elements on the wiring layout of the array substrate in the display apparatus, and the presence of the island structures can reduce the dependence of the light-emitting elements on the film layer structure in the array substrate, thereby improving the transfer versatility of the light-emitting elements, making them suitable for various types of display apparatuses.

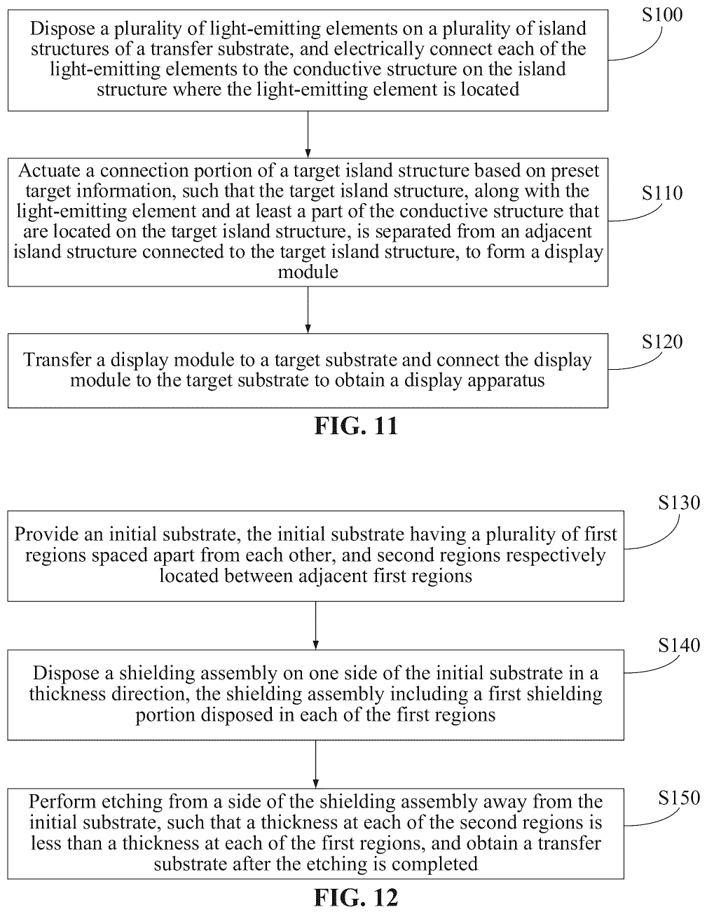

According to a third aspect, referring to FIG. 11, an embodiment of the present disclosure provides a transfer method for a light-emitting element, applied to the transfer substrate according to any of the foregoing implementations to transfer the light-emitting element. The transfer method includes the following steps:

S100: Dispose the plurality of light-emitting elements on the plurality of island structures of the transfer substrate, and electrically connect each of the light-emitting elements to the conductive structure on the island structure where the light-emitting element is located.

In step S100, the plurality of light-emitting elements are disposed on the plurality of island structures of the transfer substrate. A single island structure may have one light-emitting element disposed thereon, or may have a plurality of light-emitting elements disposed thereon. The light-emitting elements are electrically connected to the conductive structure. By controlling the conduction of the conductive structure, control over whether the light-emitting elements emit light can be achieved.

S110: Actuate a connection portion of a target island structure based on preset target information, such that the target island structure, along with the light-emitting element and at least a part of the conductive structure that are located on the target island structure, is separated from an adjacent island structure connected to the target island structure, to form a display module.

In step S110, the preset target information includes information such as position information or a serial number of the target island structure that needs to be transferred. By actuating the connection portion of the target island structure corresponding to the preset target information according to the preset target information, the target island structure can be separated from an adjacent island structure; besides, at least a part of the light-emitting element, the driving circuit, and the conductive structure on the target island structure can be separated from the transfer substrate together with the island structure, forming a display module.

S120: Transfer the display module to a target substrate and connect the display module to the target substrate to obtain a display apparatus.

In step S120, since the display module contains the island structure and at least a part of the conductive structure, the display module is less affected by the structural limitations of the array substrate and has strong versatility, making it suitable for different target substrates to form different display apparatuses. The display module is transferred to the target substrate, and the part of the conductive structure present in the display module is connected to the conductive structure on the island structure adjacent to the display module on the target substrate to form a complete circuit.

Specifically, equipment for executing the aforementioned transfer method for a light-emitting element may be a micro-transfer integrated system, and control equipment may be, for example, a PC, a tablet, a server, or a cloud platform.

According to a fourth aspect, referring to FIG. 12, an embodiment of the present disclosure provides a preparation method of a transfer substrate, including the following steps:

S130: Provide an initial substrate, the initial substrate having a plurality of first regions spaced apart from each other, and second regions respectively located between adjacent first regions.

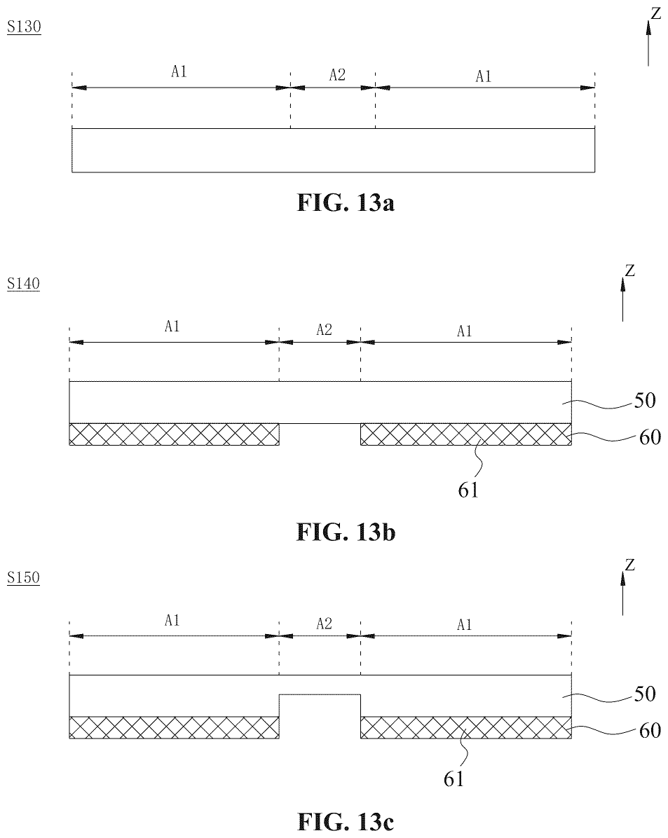

Referring to FIG. 13a, in step S130, the initial substrate 50 is configured to form the island structures and the connection portions in the transfer substrate. The first regions A1 in the initial substrate 50 correspond to the island structures in the transfer substrate, and the second regions A2 in the initial substrate 50 correspond to the connection portions in the transfer substrate.

S140: Dispose a shielding assembly on one side of the initial substrate in a thickness direction, the shielding assembly including a first shielding portion disposed in each of the first regions.

Referring to FIG. 13b, in step S140, the first shielding portion 61 is disposed at the first region A1, that is, the first shielding portion 61 is disposed corresponding to the position of the island structure 10. The presence of the first shielding portion 61 can reduce the etching impact on the first region A1 in the initial substrate 50 during the subsequent etching processes.

S150: Perform etching from a side of the shielding assembly away from the initial substrate, such that a thickness at each of the second regions is less than a thickness at each of the first regions, and obtain the transfer substrate after the etching is completed.

Referring to FIG. 13c, in step S150, due to the presence of the first shielding portion 61, the etching impact on the first region A1 is less than that on the second region A2. Therefore, compared to the first region A1, the thickness reduction of the second region A2 is greater, thereby enabling the first region A1 to form the island structure and the second region A2 to form the connection portion for connecting adjacent island structures 10.

It should be noted that, in addition to the first shielding portion 61 disposed at the first region A1, the shielding assembly 60 may also include a second shielding portion disposed at the second region A2. However, the hindering effect of the second shielding portion on the etching reaction is relatively small, that is, the second region A2 of the initial substrate will still undergo thickness reduction due to the etching reaction. This design can limit the degree of thickness reduction in the second region A2, thereby improving the preparation accuracy of the transfer substrate.

In some optional embodiments, the island structure 10 and the connection portion 20 are formed through a Deep Reactive Ion Etching (DRIE) process. Specifically, the initial substrate is a silicon-based substrate. First, a SiO₂ film is deposited on one side of the silicon-based substrate in the thickness direction. Next, a photoresist layer is coated on the side of the SiO₂ film away from the silicon-based substrate, and selective exposure, development, and hard baking are performed to form a mask layer made of photoresist. The region covered by the photoresist is the first region, and the region not covered by the photoresist is the second region. Then, hydrofluoric acid is used to perform wet etching on the SiO₂ film in the region not covered by the photoresist, i.e., the second region. After the SiO₂ film in the second region is completely etched, the silicon-based substrate is placed in acetone to completely remove the photoresist. Subsequently, deep reactive ion etching technology is used to etch the region of the silicon-based substrate not covered by the SiO₂ film, i.e., the second region, to reduce the silicon-based material at the second region, thereby forming the connection portion. Finally, the silicon-based substrate is immersed in a hydrofluoric acid solution to completely remove the SiO₂ film, thus forming the island structures and connection portions in the transfer substrate.

Although the implementation manners of the present disclosure are described as above, the contents of the present disclosure are only to facilitate the understanding of the present disclosure, but should not be construed as limiting the present disclosure. It should be noted that for a person of ordinary skill in the art, several improvements and modifications may further be made without departing from spirits and scope of the present disclosure. Improvements and modifications in the implementation manners and details can be made, but the protection scope of the present disclosure shall still be governed by the scope defined in the attached claim.

The foregoing descriptions are merely specific implementations of this application. A person skilled in the art can clearly understand that, for convenience and brevity of description, reference may be made to corresponding processes in the foregoing method embodiments for the above-described connections. Details are not described herein again. It should be understood that the protection scope of this application is not limited herein. Any equivalent modification or replacement readily figured out by a person skilled in the art within the technical scope disclosed in the present disclosure shall fall within the protection scope of the present disclosure.

1. A transfer substrate, comprising:
a plurality of island structures spaced apart from each other, wherein each of the island structures is configured to place a to-be-transferred element;
a conductive structure disposed on each of the island structures, and configured to be electrically connected to the to-be-transferred element; and
a connection portion configured to connect at least two adjacent ones of the island structures;
wherein the connection portion is a separable connection structure, and is configured to separate, upon being actuated, the island structures connected by the connection portion.

2. The transfer substrate according to claim 1, wherein the conductive structure comprises a plurality of first signal lines and a plurality of second signal lines, any one of the first signal lines in combination with any one of the second signal lines is configured to be electrically connected to different terminals of the to-be-transferred element, and each of the first signal lines is disposed on the plurality of island structures and connected to the to-be-transferred elements on the plurality of island structures;
wherein the first signal lines are disposed on the island structures, extend across a spaced-apart region between adjacent island structures, and are configured to be broken simultaneously within the spaced-apart region upon separation of two connected island structures.

3. The transfer substrate according to claim 2, wherein each of the second signal lines is disposed on the plurality of island structures and connected to the to-be-transferred elements on the plurality of island structures;
wherein the second signal lines are disposed on the island structures, extend across a spaced-apart region between adjacent island structures, and are configured to be broken simultaneously within the spaced-apart region upon separation of two connected island structures.

4. The transfer substrate according to claim 2, wherein in a thickness direction of the island structures, projections of the first signal lines respectively overlap with projections of the connection portions.

5. The transfer substrate according to claim 2, wherein a plurality of the island structures are arranged side by side in an extension direction of each of the first signal lines.

6. The transfer substrate according to claim 2, wherein each of the island structures is further configured to provide a space for placing a plurality of to-be-transferred elements; a plurality of the first signal lines are disposed on the same island structure, comprising at least one of first signal lines connected in one-to-one correspondence to at least one of the to-be-transferred elements located on the same island structure and/or a first signal line simultaneously connected to at least one of the to-be-transferred elements located on the same island structure; and
a plurality of the second signal lines are disposed on the same island structure, comprising at least one of second signal lines connected in one-to-one correspondence to at least one of the to-be-transferred elements located on the same island structure and/or a second signal line simultaneously connected to at least one of the to-be-transferred elements located on the same island structure.

7. The transfer substrate according to claim 2, wherein the conductive structure further comprises a first conductive portion disposed on each of the island structures and connected to the first signal line, and the first signal line is connected to the to-be-transferred element through the first conductive portion; and/or
the conductive structure further comprises a second conductive portion disposed on each of the island structures and connected to the second signal line, the second signal line is connected to the to-be-transferred element through the second conductive portion.

8. The transfer substrate according to claim 2, wherein the conductive structure further comprises a driving circuit disposed on each of the island structures; the driving circuit is configured to be connected to the to-be-transferred element, and the first signal line and the second signal line are both connected to the driving circuit to control turn-on or turn-off of the driving circuit, whereby an operating state of the to-be-transferred element is controlled.

9. The transfer substrate according to claim 1, wherein a structural strength of at least a part of the connection portion is less than a structural strength of the island structure.

10. The transfer substrate according to claim 9, wherein the connection portion comprises a main body portion and a weakened portion; a structural strength of the weakened portion is less than a structural strength of the main body portion and less than the structural strength of the island structure.

11. The transfer substrate according to claim 10, wherein a width of the weakened portion is less than a width of the main body portion; and/or
a thickness of the weakened portion is less than a thickness of the main body portion.

12. The transfer substrate according to claim 10, wherein in a direction from the main body portion toward the weakened portion, a width of the connection portion decreases gradually; and/or
in the direction from the main body portion toward the weakened portion, a thickness of the connection portion decreases gradually.

13. The transfer substrate according to claim 9, wherein the island structure and the connection portion form an integral structure, and a thickness of the connection portion is less than a thickness of the island structure.

14. The transfer substrate according to claim 1, wherein a material of the island structures comprises silicon; and/or
a thickness of each of the island structures is W, wherein W satisfies 20 μm≤W≤500 μm.

15. The transfer substrate according to claim 2, wherein the connection portion comprises a base and a metal wiring layer stacked on one side of the base; and/or
the connection portion comprises highly doped polycrystalline silicon;
the plurality of first signal lines are respectively disposed on the connection portions, and/or
the plurality of second signal lines are respectively disposed on the connection portions.

16. A display apparatus, comprising:
a plurality of island structures separated from the transfer substrate according to claim 1; and
a plurality of light-emitting elements, disposed on the plurality of island structures respectively, wherein each of the light-emitting elements is electrically connected to the conductive structure on the island structure where the light-emitting element is located.

17. A transfer method for a light-emitting element, the transfer method being applied to the transfer substrate according to claim 1, comprising:
disposing a plurality of light-emitting elements on a plurality of island structures of the transfer substrate, and electrically connecting each of the light-emitting elements to the conductive structure on the island structure where the light-emitting element is located;
actuating a connection portion of a target island structure based on preset target information, whereby the target island structure, along with the light-emitting element and at least a part of the conductive structure that are located on the target island structure, is separated from an adjacent island structure connected to the target island structure, to form a display module; and
transferring the display module to a target substrate and connecting the display module to the target substrate to obtain a display apparatus.

18. A preparation method of a transfer substrate, comprising:
providing an initial substrate, the initial substrate having a plurality of first regions spaced apart from each other, and second regions respectively located between adjacent first regions;
disposing a shielding assembly on one side of the initial substrate in a thickness direction, the shielding assembly comprising a first shielding portion disposed in each of the first regions; and
performing etching from a side of the shielding assembly away from the initial substrate, whereby a thickness at each of the second regions is less than a thickness at each of the first regions, and obtaining the transfer substrate after the etching is completed.
